(19) United States
(12) Patent Application Publication
(10) Pub. No.: US 2003/0038358 A1
(43) Pub. Date: Feb. 27, 2003

(54) Semiconductor package without outer leads

(75) Inventors: Jansen Chiu, Kaohsiung (TW); Taurus Chao, Wandan Shiang (TW)

Correspondence Address: DOUGHERTY & TROXELL, SUITE 1404, 5205 LEESBURG PIKE, FALLS CHURCH, VA, 22041, US

(73) Assignee: Walton Advanced Electronics LTD

(21) Appl. No.: 09/933,757

(22) Filed: Aug. 22, 2001

(51) Int. Cl. H01L 23/22

(52) U.S. Cl. 257/687

(57) ABSTRACT

A semiconductor package without outer leads such as QFN, SON is disclosed. The semiconductor package includes a die, a molding compound sealing the die, a plurality of metal leads, a plurality of metal bonding wires electrically connecting the die with the metal leads, and a plurality of metal support boards surrounded by the metal leads. The metal support boards support the die together by adhering and are used for being the power connecting terminals or ground potentials. Thus, the semiconductor package has a smaller thermal stress between the die and the metal support boards to avoid a warpage of the package or a delamination and a less noise interference.

### FIELD OF THE INVENTION

The present invention is relating to a semiconductor package without outer leads such as QFN (Quad Flat Non-leaded) package, SON (Small Outline Non-leaded) package, particularly to a semiconductor package having a plurality of die pads.

### BACKGROUND OF THE INVENTION

It is familiar that a semiconductor package includes a die sealed by a molding compound of insulating and thermosetting resin for protecting from the injury of hostile environment. A lead frame (metal leads) is used as an electrically connecting carrier of the die for mounting onto to a printed circuit board.

With small-sized trend of semiconductor package, a semiconductor package with metal pads replacing of outer leads had been brought up from U.S. Pat. No. 6,143,981 “plastic integrated circuit package and method and lead frame for making the package” to decrease the surface footprint. As shown in FIG. 1, a semiconductor package 10 comprises a semiconductor die 11, a molding compound 12, a plurality of metal leads 14, and a metal die pad 13, wherein the metal die pad 13 and the plurality of metal leads 14 are made from a lead frame 20 (as shown in FIG. 2). The plurality of metal leads 14 are connected to the perimeters 21 of lead frame 20 before molding process, and the metal die pad 13 is connected to the perimeters 21 of lead frame 20 by two tie bars 22. In the semiconductor package 10, the upper surface 16 of the metal die pad 13 is adhered with the die 11, and the lower surface 17 of the metal die pad 13 is exposed from the molding compound 12. The metal bonding wires 15 electrically connect the bonding pads of die 11 with the upper surface of metal leads 14, and the lower surface of metal leads 14 is exposed from the molding compound 12 to be connecting terminals of the semiconductor package 10 for surface mounting to a printed circuit board. However, in the semiconductor package mentioned above, there are two quite mismatching coefficients of thermal expansion (CTE) between the metal die pad 13 made of copper and the die 11 made of semiconductor material, i.e. a big thermal stress in the interface of the die 11 and the metal die pad 13 with a large area will be caused, resulting in warpage of the semiconductor package 10 or delamination between the die 11 and metal die pad 13. Besides, the smaller the surface mounting area of semiconductor package 10 is, the more consideration about the problem of noise interference should be taken.

### SUMMARY

The object of the present invention is to provide a semiconductor package without outer leads. The metal support boards are surrounded by a plurality of leads inside the molding compound, and support the die together to avoid causing a big thermal stress between the metal support boards and the die and decrease warpage of the semiconductor package or delamination. Besides, the noise interference also is decreased. The semiconductor package without outer leads in accordance with the present invention comprises:

a die having an upper surface, a lower surface, and a plurality of bonding pads formed on the upper surface of the die;

a plurality of metal support boards fixing the lower surface of the die together;

a plurality of metal leads surrounding the plurality of metal support boards, each metal lead having an upper surface and a lower surface;

a plurality of metal bonding wires electrically connecting the bonding pads of the die with the upper surfaces of corresponding metal leads; and

a molding compound sealing the die, metal bonding wires, and the upper surfaces of metal leads, at least exposing the partial lower surfaces of the plurality of metal leads.

### DESCRIPTION OF THE DRAWINGS

FIG. 1 is a cross-sectional view of a semiconductor package disclosed in U.S. Pat. No. 6,143,981 “plastic integrated circuit package and method and lead frame for making the package”.

FIG. 2 is a top view of a lead frame used for making the semiconductor package disclosed in U.S. Pat. No. 6,143,981 “plastic integrated circuit package and method and lead frame for making the package”.

FIG. 3 is a bottom view of a semiconductor package in accordance with the first embodiment of the present invention.

FIG. 4 is a top perspective view of the semiconductor package in accordance with the first embodiment of the present invention.

FIG. 5 is a cross-sectional view of the semiconductor package along FIG. 4 line 5-5 in accordance with the first embodiment of the present invention.

FIG. 6 is a cross-sectional view of the semiconductor package along FIG. 4 line 6-6 in accordance with the first embodiment of the present invention.

FIG. 7 is a bottom view of a semiconductor package in accordance with the second embodiment of the present invention.

FIG. 8 is a cross-sectional view of the semiconductor package in accordance with the second embodiment of the present invention.

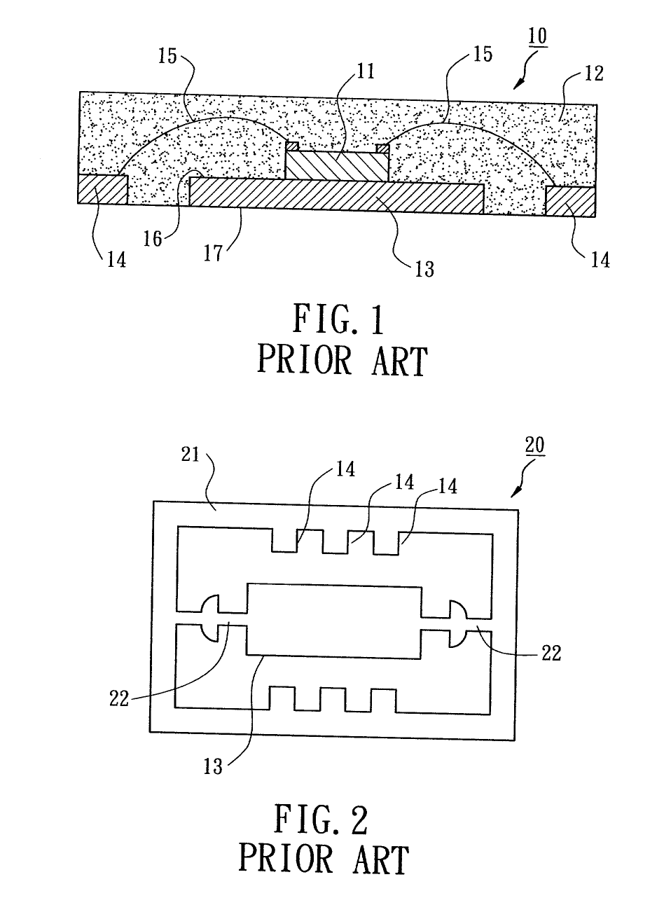

### DETAILED DESCRIPTION OF THE PRESENT INVENTION

Referring to the drawings attached, the present invention will be described by means of the embodiments below.

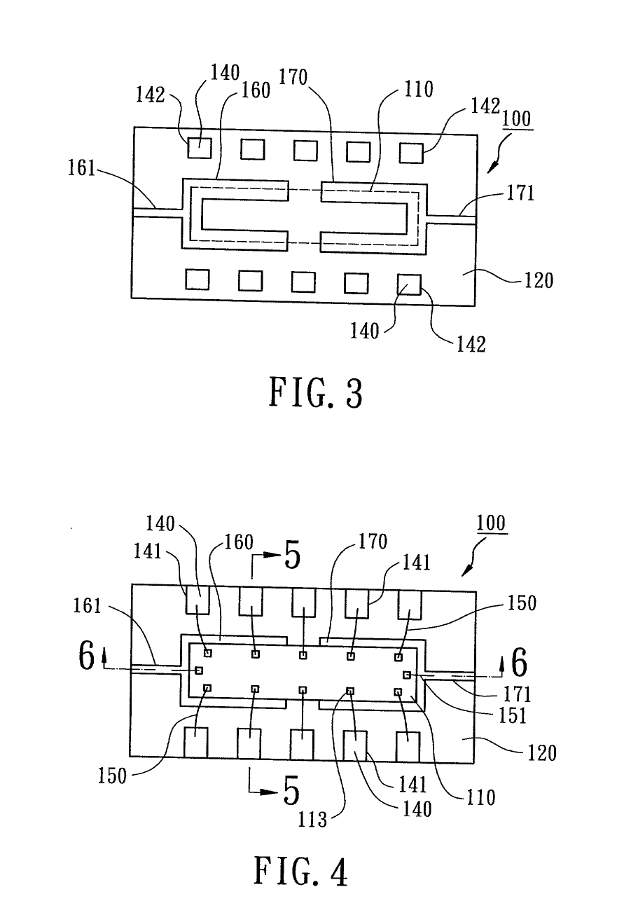

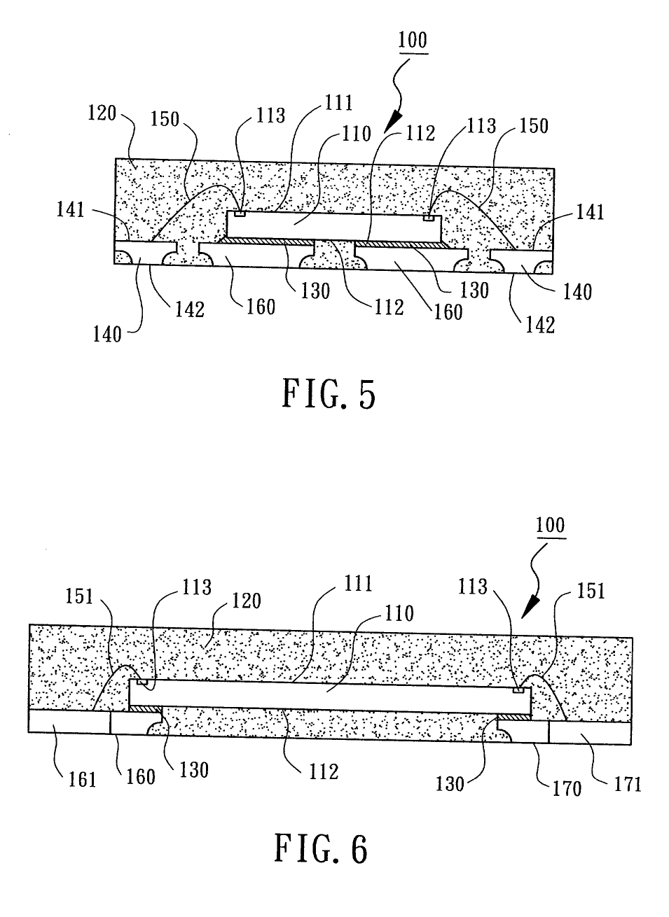

A semiconductor package of SON package (Small Outline Non-leaded package) is illustrated in the first embodiment of the present invention. FIG. 3 is a bottom view of a semiconductor package 100, FIG. 4 is a top perspective view of the semiconductor package 100, FIG. 5 is a cross-sectional view of the semiconductor package 100 along FIG. 4 line 5-5, and FIG. 6 is a cross-sectional view of the semiconductor package 100 along FIG. 4 line 6-6. As shown in FIG. 4 and 5, the semiconductor package 100 comprises a die 110, a molding compound 120, a plurality of metal bonding wires 150, a plurality of metal leads 140 and a plurality of isolated metal support boards 160, 170. In this embodiment, there are two metal support boards 160, 170 to support the die 110 together.

The die 110 is made of silicon, gallium arsenside or other semiconductor materials. It can be one kind of memory chips such as DRAM, SRAM, flash, DDR, Rambus, etc or microprocessor, logic chip, or radio frequency chip etc. The die 110 has an upper surface 111 and a lower surface 112. It is familiar that a plurality of bonding pads 113 and integrated circuit elements (not shown in the drawing) are formed on the upper surface 111 of the die 110. The thermosetting adhesive 130 such as silver paste liquid compound is printed on the metal support boards 160, 170 to adhere the lower surface 112 of die 110 onto the metal support boards 160, 170.

The first metal support board 160 and the second metal support board 170 are derived from a lead frame made of copper, alloy 42 or copper alloy. The first metal support board 160 connects a supporting bar 161 and the second metal support board 170 connects a supporting bar 171 (as shown in FIG. 3) for integrated into a lead frame before packaging process. In this embodiment, corresponding to the bonding pads 113 of the die 110 formed on the perimeters of the upper surface 111, the first metal support board 160 and the second metal support board 170 are U-shape supporting the perimeters of the lower surface 112 for suffering the pressure of wire-bonding, and each metal support board 160, 170 has a hollow portion respectively (as shown in FIG. 3 and 5). The first metal support board 160 and the second metal support board 170 support the die 110 together (as shown in FIG. 6), so that there is a flexibility in the metal support boards 160, 170 under the die 110 to overcome the thermal stress caused by the different coefficient of thermal expansion (CTE) between the die 110 and the metal support boards 160, 170 for avoiding warpage of semiconductor package 100 or delamination.

A plurality of metal leads 140 are derived from a lead frame, as shown in FIG. 3 and 4, the metal leads 140 surround the two lateral sides of the first metal support board 160 and the second metal support board 170. Each lead 140 has an upper surface 141 and a lower surface 142. The upper surfaces 141 of leads 140 are electrically interconnected with the bonding pads 113 of die 110 by metal bonding wires 150 such as gold wires or copper wires, and at least part or whole of the lower surfaces of leads 140 are uncovered by the molding compound 120 to become electrically outer connecting terminals of the semiconductor package 100. Besides, as shown in FIG. 6, the metal bonding wires 151 further electrically interconnect the power input/output terminals of the bonding pads 113 of die 110 with the supporting bars 161 or 171, then the exposing surface of the first metal support board 160 or the second metal support board 170 can become the power connecting terminal or ground potential for avoiding noise interference.

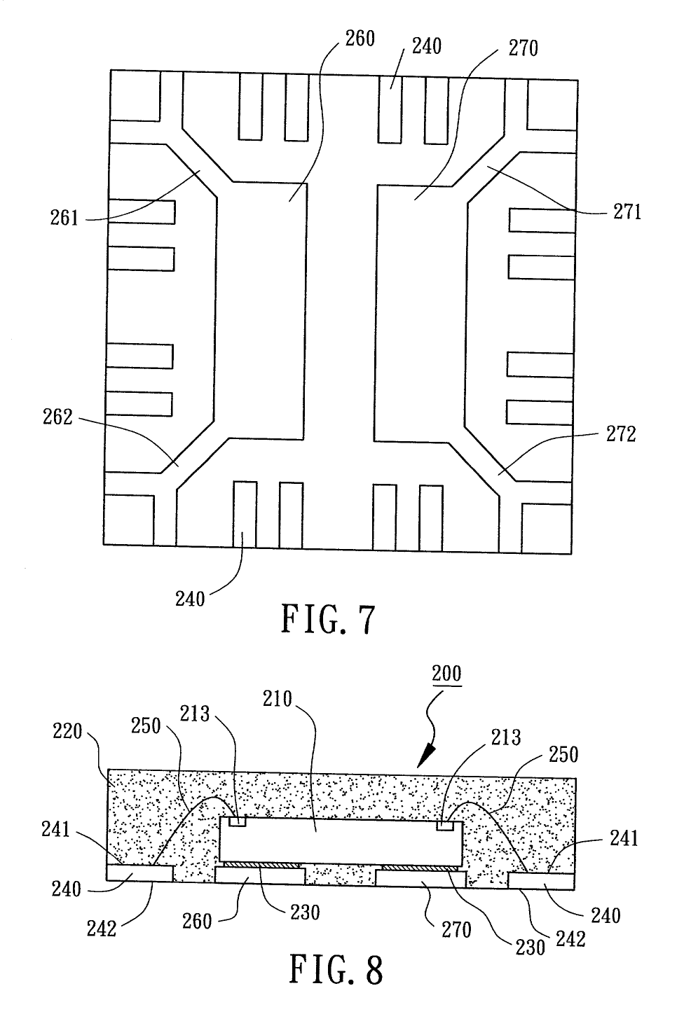

The molding compound 120 is used to protect the die 110 from invasion of moisture and dust, and is a thermosetting and insulating epoxy compound including adhesive and silica filler. The semiconductor package 100 is formed to be a lump shape without outer leads after molding or printing then curing the molding compound 120. The molding compound 120 seals the die 110, the upper surfaces 141 of metal leads 140, and the metal bonding wires 150, 160, but exposes the lower surfaces 142 of metal leads 140. In the second embodiment of the present invention, a semiconductor package 200 of QFN (Quad Flat Non-leaded) is brought up. As shown in FIG. 7 and 8, a semiconductor package 200 comprises a die 210, a molding compound 220, a plurality of metal bonding wires 250, a plurality of metal leads 240, and a plurality of metal support boards 260, 270. The die 210, the molding compound 220, and the metal bonding wires 250 are as same as those used in the first embodiment, then it is unnecessary to describe repeatedly. A plurality of metal leads 240 surround four sides of the first metal support board 260 and the second metal support board 270. The upper surfaces 241 of metal leads 240 are electrically connected with the bonding pads 213 of die 210 by metal bonding wires 250, and the lower surfaces 242 of metal leads 240 are exposed outside the molding compound 220 to become electrically outer connecting terminals. The first metal support board 260 and the second metal support board 270 are rectangular shape and support the die 210 together, such as the die 210 is adhered by adhesive 230. The first metal support board 260 connects with two supporting bars 261, 262 that extend to the comers of two lateral sides, and the second metal support board 270 also connects with two supporting bars 271, 272. Due to an interval between the first metal support board 260 and the second metal support board 270 which support the die 210 together, the thermal stress caused by a mismatching coefficient of thermal expansion (CTE) would be reduced to avoid a warpage of the package 200 or a delamination caused between the die 210 and the metal support boards 260, 270.

The above description of embodiments of this invention is intended to be illustrative and not limiting. Other embodiments of this invention will be obvious to those skilled in the art in view of the above disclosure.

What is claimed is:

1. A semiconductor package comprising:
a die having an upper surface, a lower surface, and a plurality of bonding pads formed on the upper surface of the die;
a plurality of metal support boards fixing the lower surface of the die together;
a plurality of metal leads surrounding the plurality of metal support boards, each metal lead having an upper surface and a lower surface;
a plurality of metal bonding wires electrically connecting the bonding pads of the die with the upper surfaces of the corresponding metal leads; and
a molding compound sealing the die, the metal bonding wires, and the upper surfaces of the metal leads, but at least exposing the partial lower surface of the metal leads.

2. The semiconductor package in accordance with claim 1, comprising two metal support boards.

3. The semiconductor package in accordance with claim 2, wherein each metal support board is U type fixing the perimeters of the lower surface of the die.

4. The semiconductor package in accordance with claim 1, wherein the plurality of metal leads and the plurality of metal support boards are made from a same metal material.

5. The semiconductor package in accordance with claim 1, wherein the plurality of metal leads surround the two lateral sides of the plurality of metal support boards.

6. The semiconductor package in accordance with claim 1, wherein the plurality of metal leads surround four sides of the plurality of metal support boards.

7. The semiconductor package in accordance with claim 1, wherein each metal support board connects with at least a tie bar for bonding at least one metal bonding wire.
